(19) United States
(12) Patent Application Publication
(10) Pub. No.: US 2007/0231251 A1
(43) Pub. Date: Oct. 4, 2007

(54) Capacitor Film Forming Material

(75) Inventors: Atsushi Itsuki, Naka-gun (JP); Akio Yanagisawa, Naka-gun (JP); Nobuyuki Soyama, Naka-gun (JP)

Correspondence Address: DARBY & DARBY P.C., P.O. BOX 770, Church Street Station, New York, NY, 10008-0770, US

(73) Assignee: Mitsubishi Materials Corporation, Tokyo (JP)

(21) Appl. No.: 11/570,092

(22) PCT Filed: Jun. 10, 2005
(86) PCT No.: PCT/JP05/10664

§ 371 Date: Mar. 7, 2007

(30) Foreign Application Priority Data
Jun. 11, 2004 (JP) 2004-173596

(51) Int. Cl. H01L 21/316

(52) U.S. Cl. 423/608; 427/255.6

(57) ABSTRACT

Provided is a novel capacitor film forming material having a high growth rate and excellent step coverage, and obtained is a hafnium-containing film having excellent characteristics as a capacitor film with a high dielectric constant and a low reactivity with Si.

A capacitor film forming material comprising a hafnium oxide film provided in a semiconductor memory device, is a capacitor film forming material in which the forming material comprises the organic hafnium compound of Hf(R¹R²N)₄ or Hf(OR³)₄₋ₙ(R⁴)ₙ and the content of Nb as an inevitable compound is 1 ppm or less.

### TECHNICAL FIELD

The present invention relates to a capacitor film forming material suitable for a forming material of HfO₂, HfON or the like which is promising as a novel capacitor film, and a method for producing a capacitor film using the forming material.

### BACKGROUND ART

In general, a tantalum oxide thin film is used as such kind of the capacitor films provided in a semiconductor memory device and Ta(OCH₃)₅, Ta(OC₂H₅)₅ or the like is used as a forming material for forming a tantalum oxide thin film. However, there have been difficulties in workability, including that these forming materials were partially crystallized at room temperature, and further there have been difficulties that the moisture content had to be controlled precisely upon film formation in order to make the formed film uniform, because these forming materials were high in hydrolyzability due to moisture in air.

With regard to a method for forming a tantalum oxide thin film using an MOCVD method, as a measure for solving the problems described above, a method for forming a tantalum oxide thin film, which comprises using Ta(sec-OC₄H₉)₅ as raw materials, is disclosed (for example, see Patent Document 1). The forming materials described in this Patent Document 1 have excellent workability because of high vapor pressure and a low reactivity with water, and thus can form a uniform and good tantalum oxide thin film.

[Patent Document 1] JP-A No. 8-260151 (claim 1 and paragraphs [0002] to [0006])

### DISCLOSURE OF THE INVENTION

However, a Ta compound as described in Patent Document 1 had a problem in that it has a composition containing no an Nb element but the Nb element is necessarily contained as an inevitable compound upon the synthesis reaction thereof. For example, when Ta(OC₂H₅)₅ is analyzed, it is clear that Nb is contained in an amount of 5 ppm or more. The reason why the Nb element is contained in the Ta compound as described above is attributed to that the Nb element is highly similar to the Ta element in terms of the chemical structure and the behavior, and hence the Nb element can not be easily removed from the Ta compound. In the case that the Nb element as the inevitable compound is contained in the Ta compound, it had a problem that, in forming the tantalum oxide thin film, Nb first reacts with oxygen at a low temperature of less than 200° C. to form Nb₂O₅ and this Nb₂O₅ is formed on a substrate at a temperature of about 300° C. and acts as a nucleus upon film formation. Subsequently Ta reacts with oxygen to form Ta₂O₅ and a Ta₂O₅ film is formed around the nucleus formed on the substrate, and thus a composite oxide film of Nb and Ta is formed and the tantalum oxide thin film is inferior in adhesion with metals such as Pt, Ru, Ir and TiN serving as the base. Further, if the Nb element contained as the inevitable compound, the vaporization characteristics become unstable, the volatility is not good, the film formation rate is lowered, and the step coverage of the tantalum oxide thin film formed is deteriorated.

Further, although the problems were solved by reducing the content of the Nb element in the Ta compound, first of all, since the crystallization temperature of the tantalum oxide thin film is as low as 600° C., its stability with Si having a higher crystallization temperature of 700° C. or higher is required, and Ta reacts with Si to form TaSi (tantalum silicide), it could not be said that the tantalum oxide thin film had sufficient characteristics as a capacitor film. Thus the search for a new material to replace the tantalum oxide thin film has been performed.

It is an object of the present invention is to provide a novel capacitor film forming material having a high growth rate and excellent step coverage, and a method for producing a capacitor film using the forming material.

It is another object of the present invention to provide a capacitor film forming material capable of obtaining a hafnium-containing film having excellent characteristics as a capacitor film with a high dielectric constant and a low reactivity with Si, and a method for producing a capacitor film using the forming material.

The invention as claimed in claim 1 is a capacitor film forming material comprising a hafnium oxide film provided in a semiconductor memory device, in which the forming material comprises an organic hafnium compound and the content of Nb as an inevitable compound is 1 ppm or less.

In the invention as claimed in claim 1, the organic hafnium compound having a content of Nb as the inevitable compound of 1 ppm or less can be used as the capacitor film forming material to form HfO₂, HfON or the like having a high growth rate and excellent step coverage. Such HfO₂, HfON or the like has a high dielectric constant and a low reactivity with Si, and therefore is promising as a capacitor film having excellent characteristics.

The invention as claimed in claim 2 is the forming material according to claim 1, in which the general formula of the organic hafnium compound is represented by the following formula (1):
Hf(R¹R²N)₄ (1)
(wherein R¹ and R² are each a straight or branched alkyl group having 1 to 4 carbon atoms and R¹ and R² may be the same or different from each other.)

The invention as claimed in claim 3 is the forming material according to claim 1, in which the general formula of the organic hafnium compound is represented by the following formula (2):
Hf(OR³)₄₋ₙ(R⁴ )ₙ (2)
(wherein R³ is a straight or branched alkyl group having 1 to 4 carbon atoms, R⁴ is a chelate coordination compound, and n is an integer of 0 to 4.)

The invention as claimed in claim 4 is a method for producing a capacitor film, which comprises producing a capacitor film comprising a hafnium oxide film by a metal organic chemical vapor deposition process using the forming material according to any one of claims 1 to 3.

In the invention as claimed in claim 4, the hafnium oxide film such as HfO₂ and HfON having a high growth rate and excellent step coverage can be formed. Such hafnium oxide film has a high dielectric constant and a low reactivity with Si, and therefore is promising as a capacitor film having excellent characteristics.

According to the invention, the organic hafnium compound having a content of Nb as the inevitable compound of 1 ppm or less can be used as the capacitor film forming material to form HfO₂, HfON or the like having a high growth rate and excellent step coverage. Such HfO₂, HfON or the like has a high dielectric constant and a low reactivity with Si, and therefore is promising as the capacitor film having excellent characteristics.

### BRIEF DESCRIPTION OF THE DRAWINGS

FIG. 1 is a schematic diagram of an MOCVD apparatus

FIG. 2 is a cross-sectional view of a substrate for explaining a method of determining a step coverage upon film formation through an MOCVD method.

### BEST MODE FOR CARRYING OUT THE INVENTION

Next, preferred embodiments of the present invention will be described based on the accompanying drawings.

The capacitor film forming material according to the invention is a capacitor film forming material comprising a hafnium oxide film provided in a semiconductor memory device and the characteristic structure if the forming material is characterized in that the forming material comprises an organic hafnium compound and the content of Nb as an inevitable compound is 1 ppm or less. The organic hafnium compound having a content of Nb as the inevitable compound of 1 ppm or less can be used as a capacitor film forming material to form HfO₂, HfON or the like having a high growth rate and excellent step coverage. Such HfO₂, HfON or the like has a high dielectric constant and a low reactivity with Si, and therefore has excellent characteristics as a capacitor film. The reason why the content of Nb as an inevitable compound is defined to 1 ppm or less is that, in the case of exceeding 1 ppm, Nb₂O₅ is formed as a nucleus for film formation during film formation, and hence adhesion of the formed film is deteriorated, a uniform film is not formed and the step coverage is poor. A preferred content of Nb is 0.15 to 0.2 ppm.

The organic hafnium compound constituting the forming material according to the invention is preferably the compound represented by the following formula (1):
Hf(R¹R²N)₄ (1)
(wherein R¹ and R² are each a straight or branched alkyl group having 1 to 4 carbon atoms and R¹ and R² may be the same or different from each other.)

Specific examples of the compound represented by the above general formula (1) include Hf[(CH₃)₂N]₄, Hf[(C₂H₅)₂N]₄ and Hf[(CH₃)(C₂H₅)N]₄.

The organic hafnium compound is preferably the compound represented by the following formula (2):
Hf(OR³)₄₋ₙ(R⁴)ₙ (2)
(wherein R³ is a straight or branched alkyl group having 1 to 4 carbon atoms, R⁴ is a chelate coordination compound, and n is an integer of 0 to 4.)

Specific examples of the compound represented by the above general formula (2) include Hf[O(CH₃)]₄, Hf[O(C₂H₅)]₄, Hf[O(C₃H₇)]₄, Hf[O(n-C₄H₉)]₄₁, Hf[O(t-C₄H₉)]₄₁, Hf[O(s-C₄H₉)]₄₁, Hf[O(t-C₄H₉)]₂(dpm)₂ and Hf[O(t-C₄H₉)]₂(Cp)₂. Further, dpm represents dipivaloylmethane and Cp represents a cyclopentadienyl group.

The forming material according to the invention is obtained in the following manner.

First, a commercially available hafnium tetrachloride is prepared. Usually, the commercially available hafnium tetrachloride contains about 500 to 100 ppm of Nb as an inevitable compound. Thereafter, the commercially available hafnium tetrachloride is dissolved in concentrated hydrochloric acid to prepare a dissolved solution, and the dissolved solution is kept at a temperature of 60° C. and stirred for 24 hours. After stirring, hydrochloric acid is removed from the dissolved solution to obtain a crystalline white solid. Then, a mixed solution is prepared by mixing 1 N hydrochloric acid and citric acid at a weight ratio of hydrochloric acid : citric acid=1:1000, and the crystalline white solid obtained is dissolved the mixed solution. When the crystalline white solid is dissolved in the mixed solution, an ocher solid is precipitated. The ocher solid is filtered because the precipitate is a hydroxide containing Nb. The filtrate obtained by filtration is neutralized with ammonia gas and the dissolved solution is concentrated to obtain a crystalline solid. Further, the crystalline solid is kept at 1000° C., chlorine gas is introduced thereto in a predetermined proportion, specifically a proportion of 100 ccm, for about 2 hours to obtain the purified product of hafnium tetrachloride. The content of Nb in hafnium tetrachloride is adjusted to about 1 ppm through the purification as described above. By repeatedly carrying out the processes of dissolving the crystalline white solid in a mixed solution of hydrochloric acid and citric acid, and filtering the ocher solid thus obtained, the content of Nb in hafnium tetrachloride can be extremely reduced. The forming material according to the invention is obtained by synthesizing the desired organic hafnium compound using the purified hafnium tetrachloride as raw materials of the organic hafnium compound.

A metal organic chemical vapor deposition (hereinafter referred to as an MOCVD process) is suitable for a method for forming a capacitor film using the forming material according to the invention, but the film may be formed by an atomic layer deposition (ALD process).

Further, the forming material according to the invention may be dissolved in an organic solvent in a predetermined proportion to use as raw materials of the solution. Examples of the solvent used in this case include an N-containing compound such as diamine, a hydrocarbons having 1 to 20 carbon atoms, an alcohol such as butanol, and an ether such as THF. The ratio of the forming material and the organic solvent can be appropriately adjusted according to a film forming apparatus, characteristics of a substrate as an object for film formation and types of the film to be formed.

Hereinbelow, a method for forming a capacitor film comprising a hafnium oxide thin film using the forming material according to the invention by an MOCVD process will be described.

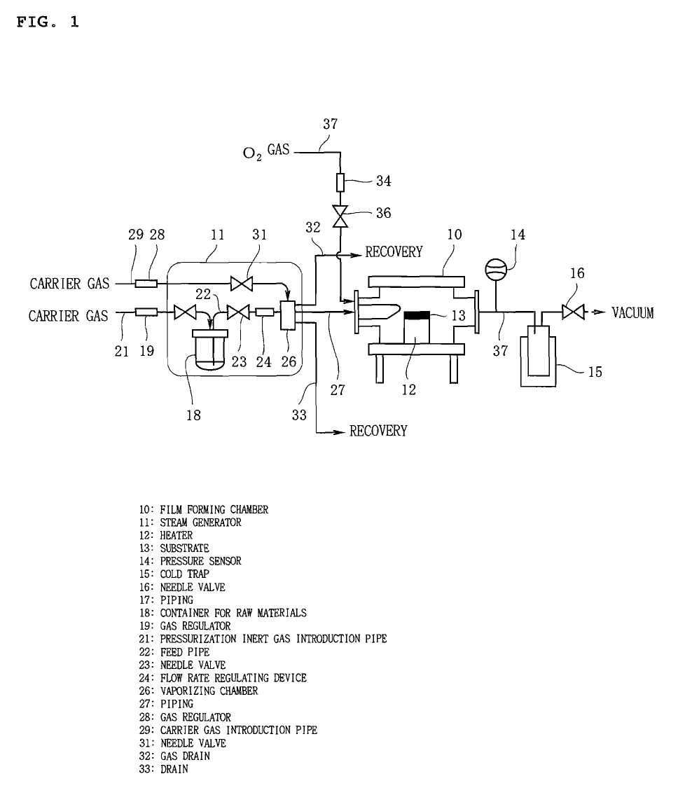

As shown in FIG. 1, the MOCVD apparatus is provided with a film forming chamber 10 and a steam generator 11. A heater 12 is arranged in the inside of the film forming chamber 10 and a substrate 13 is held on the heater 12. The inside of the film forming chamber 10 is evacuated by a piping 17 equipped with a pressure sensor 14, a cold trap 15 and a needle valve 16. An oxygen source introduction pipe 37 is connected via a needle valve 36 and a gas regulator 34 to the film forming chamber 10. The steam generator 11 is provided with a container for raw materials 18 for storing the capacitor film forming material of the invention as raw materials. In the present embodiment, as the capacitor film forming material, a forming material comprising the organic hafnium compound in which the content of Nb is defined to 1 ppm or less, is used. Further, O₂ gas is used as the oxygen source. Furthermore, O₃ gas or N₂O gas can be also used as the oxygen source. A pressurization inert gas introduction pipe 21 is connected via a gas regulator 19 to the container for raw materials 18. Further, a feed pipe 22 is connected to the container for raw materials 18. A needle valve 23 and a flow rate regulating device 24 are arranged in the feed pipe 22 and the feed pipe 22 is connected to a vaporizing chamber 26. A carrier gas introduction pipe 29 is connected via a needle valve 31 and a gas regulator 28 to the vaporizing chamber 26. The vaporizing chamber 26 is further connected via a piping 27 to the film forming chamber 10. In addition, a gas drain 32 and a drain 33 are connected to the vaporizing chamber 26, respectively.

In this apparatus, a pressurization inert gas is introduced from the introduction pipe 21 into the container for raw materials 18 and a raw material solution stored in the container for raw materials 18 is delivered via the feed pipe 22 to the vaporizing chamber 26. The organic hafnium compound which has been vaporized to vapor in the vaporizing chamber 26, as the forming material, is further fed via the piping 27 to the film forming chamber 10 by the carrier gas which is introduced from the carrier gas introduction pipe 29 into the vaporizing chamber 26. In the film forming chamber 10, the vapor of the organic hafnium compound is thermally decomposed and reacted with O₂ gas introduced from the oxygen source introduction pipe 37 to form a hafnium oxide, and the hafnium oxide formed is deposited on the substrate 13 heated to form a hafnium oxide thin film. Examples of the pressurization inert gas or the carrier gas include argon, helium and nitrogen.

As described above, the forming material containing an extremely reduced amount of Nb is excellent in adhesion with the substrate because no a nucleus for film formation is resulted from Nb, and the hafnium oxide thin film having high film formation rate and excellent step coverage can be formed because the organic hafnium compound is used. The hafnium oxide thin film obtained has a high dielectric constant and a low reactivity with Si and thus functions as a capacitor film having excellent characteristics Further, the HfON thin film can be also formed by feeding not only the oxygen source such as O₀₂ as gases introduced into the film forming chamber 10 but also a nitrogen source such as N₂ gas, NH₃ gas and NH═NH. This HfON thin film also functions as a capacitor film having excellent characteristics.

### EXAMPLES

Hereinbelow, Examples of the present invention, and Comparative Examples will be described in detail.

### Example 1

First, a commercially available hafnium tetrachloride was prepared. The commercially available hafnium tetrachloride was analyzed and found to contain 100 ppm of Nb as an inevitable compound. Thereafter, 50 g of the commercially available hafnium tetrachloride was dissolved in 100 ml of concentrated hydrochloric acid to prepare a dissolved solution, and the dissolved solution was kept at a temperature of 60° C and stirred for 24 hours. After stirring, hydrochloric acid was removed from the dissolved solution to obtain a crystalline white solid. Then, a mixed solution was prepared by mixing 1 N hydrochloric acid and citric acid in a proportion of hydrochloric acid:citric acid=1:1000 in terms of a weight ratio, and the crystalline white solid obtained was dissolved the mixed solution. Subsequently, an ocher solid precipitated in the dissolved solution was filtered. The filtrate obtained by filtration was neutralized with ammonia gas. After neutralization, the dissolved solution was concentrated to obtain a crystalline solid. Further, the crystalline solid was kept at 1000° C., chlorine gas was introduced thereto in a proportion of 100 ccm for 2 hours to obtain the purified product of hafnium tetrachloride. The content of Nb in hafnium tetrachloride obtained by the purification as described above was 1 ppm.

### Example 2

Hafnium tetrachloride was obtained in the same manner as in Example 1 except that the processes of dissolving in a mixed solution of hydrochloric acid and citric acid and filtering the precipitate was repeated three times. The content of Nb in the hafnium tetrachloride obtained was 0.5 ppm.

### Example 3

Hafnium tetrachloride was obtained in the same manner as in Example 1 except that the processes of dissolving in a mixed solution of hydrochloric acid and citric acid and filtering the precipitate was repeated five times. The content of Nb in the hafnium tetrachloride obtained was 0.1 ppm.

### Example 4

Hafnium tetrachloride was obtained in the same manner as in Example 1 except that the processes of dissolving in a mixed solution of hydrochloric acid and citric acid and filtering the precipitate was repeated ten times. The content of Nb in the hafnium tetrachloride obtained was 0.05 ppm.

### Example 5

Hafnium tetrachloride was obtained in the same manner as in Example 1 except that the processes of dissolving in a mixed solution of hydrochloric acid and citric acid and filtering the precipitate was repeated twenty times. The content of Nb in the hafnium tetrachloride obtained was 0.005 ppm.

### Comparative Example 1

The commercially available hafnium tetrachloride was prepared and the hafnium tetrachloride was recrystallized fifty times from hydrochloric acid to obtain the desired hafnium tetrachloride. The content of Nb in the hafnium tetrachloride obtained was 5 ppm.

### Comparative Example 2

The commercially available hafnium tetrachloride was prepared and the hafnium tetrachloride was recrystallized thirty times from hydrochloric acid to obtain the desired hafnium tetrachloride. The content of Nb in the hafnium tetrachloride obtained was 10 ppm.

### Comparative Example 3

The commercially available hafnium tetrachloride was prepared and the hafnium tetrachloride was recrystallized twenty times from hydrochloric acid to obtain the desired hafnium tetrachloride. The content of Nb in the hafnium tetrachloride obtained was 20 ppm.

### Comparative Example 4

The commercially available hafnium tetrachloride was prepared and the hafnium tetrachloride was recrystallized ten times from hydrochloric acid to obtain the desired hafnium tetrachloride. The content of Nb in the hafnium tetrachloride obtained was 50 ppm.

### Comparative Example 5

The commercially available hafnium tetrachloride itself was used as a raw material of the organic hafnium compound. The content of Nb in the hafnium tetrachloride obtained was 100 ppm.

### Comparative Test 1

Each of hafnium tetrachloride obtained in Examples 1 to 5 and Comparative Examples 1 to 5 was used as the raw material of the organic hafnium compound to synthesize Hf(Et₂N)₄. The Hf(Et₂N)₄ was used as a capacitor film forming material. These capacitor film forming materials were used to carry out a test for film thickness per film formation time and a step coverage test shown in the following.

First, five Pt (20 nm)/SiO₂ (500 nm)/Si substrates were prepared as substrates and the substrates were installed in the film forming chamber of the MOCVD apparatus shown in FIG. 1. Then, a substrate temperature, a vaporization temperature and a pressure were set to 700° C., 100° C. and about 1.33 kPa (10 torr), respectively. O₂ gas was used as a reactant gas and its partial pressure was set at 1000 ccm. Then, Ar gas was used as a carrier gas and the forming materials were fed at a rate of 0.5 cc/min to form a hafnium oxide thin film, respectively. The substrates were taken one by one from the film forming chamber when the film formation time reached 1 minute, 5 minutes, 10 minutes, 20 minutes and 30 minutes, respectively.

(1) Test for Film Thickness Per Film Formation Time

The film thickness of the hafnium oxide thin film on the film-formed substrate was determined from a cross-sectional scanning electron microscope image.

(2) Step Coverage Test

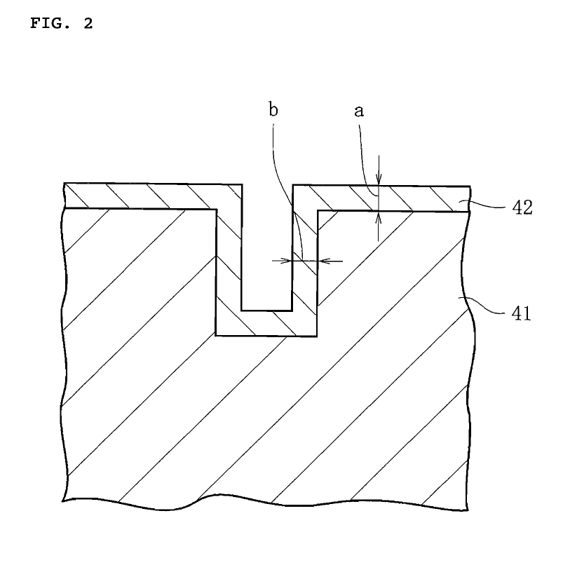

The step coverage of the hafnium oxide thin film on the film-formed substrate was determined from a cross-sectional scanning electron microscope image. The step coverage is represented by a numerical value of a/b when a thin film 42 was formed on a substrate 41 with a level difference such as grooves as shown in FIG. 2. When a/b is 1.0, it can be said that the step coverage is good because a film is uniformly formed onto the back of the groove as in the flat portion of the substrate. Meanwhile, when a/b is a numerical value of less than 1.0, it is difficult to form a film onto the back of the groove, and when a/b is a numerical value exceeding 1.0, the degree of film formation is higher in the back of the groove than in the flat portion of the substrate, and thus each step coverage is believed to be not good.

The content of Nb in the capacitor film forming material, and the obtained results of the film thickness per film formation time and the step coverage are shown in the following Table 1, respectively.

TABLE 1

| | | | Film thickness per film | | | | | | | | | |
|---|---|---|---|---|---|---|---|---|---|---|---|---|
| | | Content | formation time [nm] | | | | | Step coverage [−] | | | | |
| | Organic Hf | of Nb | 1 | 5 | 10 | 20 | 30 | 1 | 5 | 10 | 20 | 30 |
| | compound | [ppm] | min | min | min | min | min | min | min | min | min | min |
| Ex. 1 | Hf(Et₂N)₄ | 1 | 0.5 | 1 | 10 | 19 | 28 | 0.9 | 0.9 | 1 | 0.9 | 1 |
| Ex. 2 | Hf(Et₂N)₄ | 0.5 | 0.6 | 1 | 10 | 18 | 30 | 0.9 | 1 | 1 | 0.9 | 1 |
| Ex. 3 | Hf(Et₂N)₄ | 0.1 | 1 | 1.2 | 12 | 22 | 35 | 1 | 1 | 0.8 | 0.8 | 0.9 |
| Ex. 4 | Hf(Et₂N)₄ | 0.05 | 0.8 | 1.2 | 12 | 21 | 36 | 1 | 0.9 | 0.9 | 0.9 | 1 |
| Ex. 5 | Hf(Et₂N)₄ | 0.005 | 0.6 | 1.1 | 11 | 20 | 32 | 0.9 | 0.9 | 0.9 | 1 | 0.9 |
| Comp. | Hf(Et₂N)₄ | 5 | 0.8 | 1 | 1.1 | 0.2 | 0.1 | 0.1 | 0.2 | 0.01 | 0.01 | 0.002 |
| Ex. 1 | | | | | | | | | | | | |
| Comp. | Hf(Et₂N)₄ | 10 | 0.9 | 1 | 1 | 0.03 | 0.02 | 0.2 | 0.2 | 0.02 | 0.01 | 0.003 |
| Ex. 2 | | | | | | | | | | | | |
| Comp. | Hf(Et₂N)₄ | 20 | 0.7 | 0.8 | 0.7 | 0.3 | 0.02 | 0.2 | 0.1 | 0.01 | 0.01 | 0.002 |
| Ex. 3 | | | | | | | | | | | | |
| Comp. | Hf(Et₂N)₄ | 50 | 0.8 | 0.3 | 0.07 | 0.04 | 0.01 | 0.1 | 0.1 | 0.03 | 0.001 | 0.002 |
| Ex. 4 | | | | | | | | | | | | |
| Comp. | Hf(Et₂N)₄ | 100 | 0.9 | 1 | 0.5 | 0.02 | 0.02 | 0.1 | 0.2 | 0.01 | 0.002 | 0.001 |
| Ex. 5 | | | | | | | | | | | | |

### Comparative Test 2

A test for film thickness per film formation time and a step coverage test were carried out in the same manner as in Comparative Test 1 except that each hafnium tetrachloride obtained in Examples 1 to 5 and Comparative Examples 1 to 5 was used to synthesize Hf(EtMeN)₄ and the Hf(EtMeN)₄ was used as a capacitor film forming material. The content of Nb in the capacitor film forming material and the obtained results of the film thickness per film formation time and the step coverage are shown in the following Table 2, respectively.

TABLE 2

| | | | Film thickness per film | | | | | | | | | |
|---|---|---|---|---|---|---|---|---|---|---|---|---|
| | | Content | formation time [nm] | | | | | Step coverage [−] | | | | |
| | Organic Hf | of Nb | 1 | 5 | 10 | 20 | 30 | 1 | 5 | 10 | 20 | 30 |
| | compound | [ppm] | min | min | min | min | min | min | min | min | min | min |
| Ex. 1 | Hf(EtMeN)₄ | 1 | 0.3 | 1.3 | 3 | 6 | 10 | 1 | 0.9 | 0.9 | 1 | 1 |
| Ex. 2 | Hf(EtMeN)₄ | 0.5 | 0.7 | 3.4 | 6 | 13 | 18 | 0.9 | 0.9 | 0.9 | 1 | 0.8 |
| Ex. 3 | Hf(EtMeN)₄ | 0.1 | 1.2 | 6 | 12 | 24 | 35 | 1 | 0.9 | 1 | 0.8 | 0.9 |
| Ex. 4 | Hf(EtMeN)₄ | 0.05 | 0.8 | 4 | 8 | 16 | 23 | 0.9 | 1 | 1 | 0.8 | 0.8 |
| Ex. 5 | Hf(EtMeN)₄ | 0.005 | 0.8 | 3.8 | 9 | 19 | 18 | 0.9 | 1 | 0.9 | 0.8 | 1 |
| Comp. | Hf(EtMeN)₄ | 5 | 0.3 | 1 | 1.1 | 0.1 | 0.01 | 0.1 | 0.1 | 0.02 | 0.002 | 0.002 |
| Ex. 1 | | | | | | | | | | | | |
| Comp. | Hf(EtMeN)₄ | 10 | 0.5 | 2 | 1.2 | 0.02 | 0.01 | 0.2 | 0.1 | 0.01 | 0.001 | 0.001 |
| Ex. 2 | | | | | | | | | | | | |
| Comp. | Hf(EtMeN)₄ | 20 | 0.6 | 3 | 0.6 | 0.2 | 0.01 | 0.2 | 0.08 | 0.02 | 0.01 | 0.001 |
| Ex. 3 | | | | | | | | | | | | |
| Comp. | Hf(EtMeN)₄ | 50 | 0.2 | 0.1 | 0.03 | 0.02 | 0.02 | 0.1 | 0.2 | 0.01 | 0.002 | 0.002 |
| Ex. 4 | | | | | | | | | | | | |
| Comp. | Hf(EtMeN)₄ | 100 | 0.1 | 0.1 | 0.3 | 0.03 | 0.01 | 0.1 | 0.1 | 0.01 | 0.001 | 0.001 |
| Ex. 5 | | | | | | | | | | | | |

### Comparative Test 3

A test for film thickness per film formation time and a step coverage test were carried out in the same manner as in Comparative Test 1 except that each hafnium tetrachloride obtained in Examples 1 to 5 and Comparative Examples 1 to 5 was used to synthesize Hf(Me₂N)₄ and the Hf(Me₂N)₄ was used as a capacitor film forming material. The content of Nb in the capacitor film forming material and the obtained results of the film thickness per film formation time and the step coverage are shown in the following Table 3, respectively.

TABLE 3

| | | | Film thickness per film | | | | | | | | | |
|---|---|---|---|---|---|---|---|---|---|---|---|---|
| | | Content | formation time [nm] | | | | | Step coverage [−] | | | | |
| | Organic Hf | of Nb | 1 | 5 | 10 | 20 | 30 | 1 | 5 | 10 | 20 | 30 |
| | compound | [ppm] | min | min | min | min | min | min | min | min | min | min |
| Ex. 1 | Hf(Me₂N)₄ | 1 | 0.6 | 3 | 6 | 12 | 18 | 1 | 0.9 | 0.9 | 1 | 0.9 |
| Ex. 2 | Hf(Me₂N)₄ | 0.5 | 0.5 | 3 | 5 | 10 | 15 | 1 | 0.9 | 0.9 | 0.8 | 1 |
| Ex. 3 | Hf(Me₂N)₄ | 0.1 | 0.9 | 5 | 8 | 16 | 25 | 0.9 | 0.8 | 1 | 1 | 1 |
| Ex. 4 | Hf(Me₂N)₄ | 0.05 | 0.7 | 4 | 7 | 14 | 22 | 0.9 | 1 | 1 | 0.9 | 1 |
| Ex. 5 | Hf(Me₂N)₄ | 0.005 | 0.6 | 3 | 6 | 12 | 19 | 1 | 1 | 0.9 | 0.9 | 0.9 |
| Comp. | Hf(Me₂N)₄ | 5 | 0.5 | 1 | 0.9 | 0.1 | 0.1 | 0.3 | 0.1 | 0.02 | 0.008 | 0.002 |
| Ex. 1 | | | | | | | | | | | | |
| Comp. | Hf(Me₂N)₄ | 10 | 0.4 | 0.9 | 0.9 | 0.05 | 0.01 | 0.1 | 0.1 | 0.01 | 0.002 | 0.003 |
| Ex. 2 | | | | | | | | | | | | |
| Comp. | Hf(Me₂N)₄ | 20 | 0.8 | 0.8 | 0.08 | 0.3 | 0.01 | 0.2 | 0.2 | 0.02 | 0.001 | 0.001 |
| Ex. 3 | | | | | | | | | | | | |
| Comp. | Hf(Me₂N)₄ | 50 | 1 | 0.2 | 0.07 | 0.05 | 0.001 | 0.2 | 0.1 | 0.02 | 0.001 | 0.001 |
| Ex. 4 | | | | | | | | | | | | |
| Comp. | Hf(Me₂N)₄ | 100 | 0.8 | 0.4 | 0.05 | 0.01 | 0.001 | 0.3 | 0.1 | 0.01 | 0.001 | 0.001 |
| Ex. 5 | | | | | | | | | | | | |

### Comparative Test 4

A test for film thickness per film formation time and a step coverage test were carried out in the same manner as in Comparative Test 1 except that each hafnium tetrachloride obtained in Examples 1 to 5 and Comparative Examples 1 to 5 was used to synthesize Hf(OC₄H₉)₄ and the Hf(OC₄H₉)₄ was used as a capacitor film forming material. The content of Nb in the capacitor film forming material and the obtained results of the film thickness per film formation time and the step coverage are shown in the following Table 4, respectively

TABLE 4

| | | | Film thickness per film | | | | | | | | | |
|---|---|---|---|---|---|---|---|---|---|---|---|---|
| | | Content | formation time [nm] | | | | | Step coverage [−] | | | | |
| | Organic Hf | of Nb | 1 | 5 | 10 | 20 | 30 | 1 | 5 | 10 | 20 | 30 |
| | compound | [ppm] | min | min | min | min | min | min | min | min | min | min |
| Ex. 1 | Hf(OC₄H₉)₄ | 1 | 0.2 | 1 | 2 | 4 | 28 | 1 | 1 | 0.9 | 1 | 1 |
| Ex. 2 | Hf(OC₄H₉)₄ | 0.5 | 0.1 | 0.5 | 1 | 2 | 30 | 0.9 | 0.9 | 1 | 0.9 | 0.8 |
| Ex. 3 | Hf(OC₄H₉)₄ | 0.1 | 0.2 | 1.2 | 2 | 5 | 35 | 0.9 | 1 | 0.8 | 0.8 | 0.9 |
| Ex. 4 | Hf(OC₄H₉)₄ | 0.05 | 0.3 | 1.3 | 4 | 9 | 36 | 0.8 | 1 | 1 | 1 | 1 |
| Ex. 5 | Hf(OC₄H₉)₄ | 0.005 | 0.2 | 1.1 | 2 | 4 | 32 | 0.9 | 1 | 0.9 | 1 | 0.9 |
| Comp. | Hf(OC₄H₉)₄ | 5 | 0.2 | 0.8 | 0.9 | 0.8 | 0.1 | 0.05 | 0.08 | 0.02 | 0.01 | 0.002 |
| Ex. 1 | | | | | | | | | | | | |
| Comp. | Hf(OC₄H₉)₄ | 10 | 0.5 | 0.7 | 0.9 | 0.5 | 0.02 | 0.01 | 0.02 | 0.01 | 0.01 | 0.004 |
| Ex. 2 | | | | | | | | | | | | |
| Comp. | Hf(OC₄H₉)₄ | 20 | 0.7 | 0.9 | 0.5 | 0.1 | 0.02 | 0.1 | 0.02 | 0.01 | 0.006 | 0.004 |
| Ex. 3 | | | | | | | | | | | | |
| Comp. | Hf(OC₄H₉)₄ | 50 | 0.7 | 0.3 | 0.6 | 0.02 | 0.01 | 0.05 | 0.03 | 0.01 | 0.001 | 0.002 |
| Ex. 4 | | | | | | | | | | | | |
| Comp. | Hf(OC₄H₉)₄ | 100 | 0.8 | 0.9 | 0.5 | 0.02 | 0.02 | 0.08 | 0.07 | 0.01 | 0.001 | 0.001 |
| Ex. 5 | | | | | | | | | | | | |

### INDUSTRIAL APPLICABILITY

As is apparent from Tables 1 to 4, it is found that the thin films obtained by using the forming materials of Comparative Examples 1 to 5 having high contents of Nb is not increased in thickness although time progresses and the stability in film formation is not good. Further, if a capacitor film is formed by using the forming materials of Comparative Examples 1 to 5, voids may occur in the capacitor film, because the results of the step coverage are extremely bad. In contrast, for the thin films obtained by using the forming materials of Examples 1 to 5, the film formation rate was extremely high, the film thickness per film formation time was uniform and the stability in film formation was high, as compared to the case that the forming materials of Comparative Examples 1 to 5 were used. In addition, it was found that the step coverage obtained was a numeric value close to 1.0 and the film was uniformly formed onto the back of the groove as in the flat portion of the substrate.

1. A capacitor film forming material comprising a hafnium oxide film provided in a semiconductor memory device, wherein the forming material comprises an organic hafnium compound and the content of Nb as an inevitable compound is 1 ppm or less.

2. The forming material according to claim 1, wherein the general formula of the organic hafnium compound is represented by the following formula (1):
Hf(R¹R²N)₄ (1)
(wherein R¹ and R² are each a straight or branched alkyl group having 1 to 4 carbon atoms and R¹ and R² may be the same or different from each other.)

3. The forming material according to claim 1, wherein the general formula of the organic hafnium compound is represented by the following formula (2):
Hf(OR³)₄₋ₙ(R⁴)ₙ (2)
(wherein R³ is a straight or branched alkyl group having 1 to 4 carbon atoms, R⁴ is a chelate coordination compound, and n is an integer of 0 to 4.)

4. A method for producing a capacitor film, which comprises producing a capacitor film comprising a hafnium oxide film by a metal organic chemical vapor deposition using the forming material according to claim 1.

5. A method for producing a capacitor film, which comprises producing a capacitor film comprising a hafnium oxide film by a metal organic chemical vapor deposition using the forming material according to claim 2.

6. A method for producing a capacitor film, which comprises producing a capacitor film comprising a hafnium oxide film by a metal organic chemical vapor deposition using the forming material according to claim 3.
